(19) United States
(12) Patent Application Publication
(10) Pub. No.: US 2010/0259285 A1
(43) Pub. Date: Oct. 14, 2010

(54) PROVIDING FEEDBACK IN AN ELECTRONIC CIRCUIT

(75) Inventors: Kimmo Koli, Helsinki (FI); Jari Savolainen, Espoo (FI); Juha Rakkola, Espoo (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/530,089

(22) PCT Filed: Mar. 5, 2007
(86) PCT No.: PCT/IB2007/050715

§ 371 Date: May 18, 2010

(51) Int. Cl. G01R 27/26; H03M 1/00

(52) U.S. Cl. 324/686; 341/110

(57) ABSTRACT

The invention relates to an electronic circuit and a method capable of providing feedback in the electronic circuit, such that the effect of leakage currents in the circuit are minimised. The method includes the steps of storing an analogue input signal using an analogue storage device, converting the stored analogue input signal into a digital signal and storing the digital signal, converting the stored digital signal into an analogue feedback signal, and providing feedback in the electronic circuit using the analogue feedback signal.

### FIELD OF THE INVENTION

The present invention relates to providing feedback in an electronic circuit, particularly but not exclusively to a mixed-mode self-balancing bridge for a capacitive acceleration sensor.

### BACKGROUND OF THE INVENTION

Referring to FIG. 1, a capacitive accelerometer 1, also referred to as a capacitive acceleration sensor, has a moveable mass 2 arranged between first and second electrodes 3, 4. The arrangement results in first and second capacitors 5, 6 being formed between each respective electrode 3, 4 and the moveable mass 2. Any acceleration applied to the accelerometer 1 will cause a force on the mass 2, which has the effect of changing the plate separation distances of the first and second capacitors 5, 6, which will cause a change in their respective capacitances. Measuring the charge stored by the capacitors 5, 6 provides an indication of the acceleration applied to the accelerometer 1.

In order to take a measurement, a test voltage V₁, V₂ is applied across each capacitor 5, 6 of the accelerometer 1. However, the test voltages V₁, V₂ generate mechanical forces F₁, F₂, on the mass 2. Provided that the areas of the plates of the first and second capacitors 5, 6, are equal, the two forces F₁, F₂ cancel each other out if the charge on the capacitors 5, 6 is equal. The self-balancing bridge principle is therefore generally used in the front-end circuitry of capacitive acceleration sensors in order to provide a feedback control loop that adjusts the test voltages V₁. V₂ so that forces on the accelerometer mass 2 cancel out and an accurate measurement can be obtained.

Acceleration sensors are increasingly being used in a wide range of devices, for instance mobile devices such as mobile phones and personal digital assistants (PDAs). In such devices, in order to minimise component costs, sensor interface circuitry, for instance the above-described front-end circuitry for a capacitive acceleration sensor, is implemented using high density CMOS integration technology. Such technology has a high digital gate density and enables economic realization of the sensor post-processing in terms of both cost and space. In order to minimize the power consumption in sensor front-end circuitry, low sampling rates are preferably used. However, high density CMOS integration technologies result in circuits that exhibit high leakage currents that cause significant inaccuracies in stored analogue voltages, for instance those required to provide feedback in circuits such as the self-balancing bridge. To avoid such inaccuracies, sampling frequencies are increased, thus limiting the effects of the high leakage currents, but also bringing about an increase in power consumption when compared to circuits operating at lower sampling frequencies.

To avoid the drawback of increased power consumption, the sensor interface can be implemented using a separate, additional, integrated circuit optimised for low power analogue signal processing. However, this has the effect of increasing circuit board area and component manufacturing and testing costs.

### SUMMARY OF THE INVENTION

The present invention aims to address the above drawbacks. According to the invention, there is provided a method comprising the steps of using an analogue storage device of an electronic circuit to store an analogue input signal, using an analogue to digital converter of the electronic circuit to convert the stored analogue input signal into a digital signal and storing the digital signal, using a digital to analogue converter of the electronic circuit to convert the stored digital signal into an analogue feedback signal, and providing feedback in the electronic circuit using the analogue feedback signal.

The present invention therefore provides a method by which feedback can be provided in an electronic circuit without the analogue storage device used in the circuit being required to store the analogue input signal for any longer than is necessary for the analogue signal to be converted into the digital domain. Accordingly, the effects of leakage currents on the signal stored by the analogue storage device can be greatly reduced.

The method can further comprise the step of sampling the analogue input signal, wherein the step of storing the analogue input signal comprises storing the sampled analogue input signal.

The method steps of storing the analogue input signal, converting the stored analogue input signal into a digital signal and storing the digital signal can be performed in a first sampling period. The steps of converting the stored digital signal into an analogue feedback signal and providing feedback in the electronic circuit using the analogue feedback signal can be performed in a second sampling period occurring after the first sampling period.

The method can further comprise performing, in each sampling period n of a plurality of sampling periods occurring after the first sampling period, the method steps of converting the digital signal stored in the (n−1)^{th} sampling period into an analogue feedback signal and providing feedback in the electronic circuit using the analogue feedback signal, storing the analogue input signal using the analogue storage device, converting the analogue input signal stored in the n^{th} sampling period into a digital signal, and storing the digital signal obtained in the n^{th} sampling period.

The method can further comprise performing the method steps performed in each of the plurality of sampling periods in a fraction of the respective sampling period. The fraction can comprise a period of less than 1% of the sampling period.

The plurality of sampling periods can occur periodically at a sampling frequency of less than 1 kHz.

The method can further comprise providing the digital signal as an output of the electronic circuit and/or performing digital signal processing of the digital signal.

The method can further comprise powering off the analogue storage device during a period in which the analogue storage device is not required to store the analogue input signal.

The method can further comprise storing an error signal indicative of errors in the electronic circuit and adjusting said analogue input signal using said stored error signal.

The method can further comprise performing the step of converting the stored analogue input signal into a digital signal using the digital to analogue converter in a successive approximation analogue to digital converter arrangement.

The method can further comprise providing the digital to analogue converter with predetermined data and wherein the step of using the digital to analogue converter to convert the stored digital signal into an analogue feedback signal comprises using the digital to analogue converter to convert the stored digital signal and the predetermined data into the analogue feedback signal. The predetermined data can, for instance, provide an initial feedback value such that the first output of the electronic circuit is relatively accurate. Alternatively, the predetermined value can, for instance, provide a temperature dependent tuning parameter or other such parameters to improve the accuracy of the output of the electronic circuit.

According to the invention, there is further provided an electronic circuit comprising an analogue storage device for storing an analogue input signal, an analogue to digital converter arranged to convert an analogue input signal stored by the analogue storage device into a digital signal, a digital storage device arranged to store a digital signal provided by the analogue to digital converter, and a digital to analogue converter arranged to convert a digital signal stored at the digital storage device into an analogue feedback signal for providing feedback in the electronic circuit.

The analogue storage device can be implemented using a CMOS integration technology and/or the electronic circuit can comprise a CMOS integrated circuit.

The electronic circuit can further comprise a control unit arranged to power off the analogue storage device during a period when it is not required to store the analogue input signal.

The control unit can be further arranged to control the electronic circuit to operate at a sampling frequency of less than 1 kHz.

The electronic circuit can be arranged for use as the front-end circuitry for a sensor. The sensor can comprise a capacitive acceleration sensor.

The electronic circuit can be arranged to operate as a self-balancing bridge.

The electronic circuit can further comprise an error storage device for storing an error signal indicative of errors in the electronic circuit, and error adjusting circuitry for adjusting said analogue input signal using said stored error signal.

The analogue to digital converter can comprise the digital to analogue converter used in a successive approximation analogue to digital converter arrangement.

The digital storage means can comprise a digital filter.

Analogue components in the electronic circuit can be implemented using a switched capacitor arrangement.

According to the invention, there is also provided a mobile device comprising the electronic circuit according to the invention and a sensor for providing the analogue input signal.

According to the invention, there is further provided an electronic circuit comprising means for storing an analogue input signal, means for converting an analogue input signal stored by the analogue storage means into a digital signal, means for storing a digital signal provided by the analogue to digital converter, and means for converting a digital signal stored at the digital storage means into an analogue feedback signal.

### BRIEF DESCRIPTION OF DRAWINGS

Embodiments of the invention will now be described, by way of example, with reference to the accompanying drawings, in which:

FIG. 1 illustrates a capacitive acceleration sensor;

FIG. 2 schematically illustrates an electronic circuit according to the present invention connected to a sensor;

FIG. 3 is a flow diagram illustrating the processing steps performed by the electronic circuit of FIG. 2, according to the present invention;

FIG. 4 illustrates a further example of an electronic circuit according to the present invention connected to a capacitive acceleration sensor;

FIG. 5 illustrates circuitry for generating control signals for use in the circuit of FIG. 4;

FIG. 6 illustrates the circuit of FIG. 4 during an initialisation phase;

FIG. 7 illustrates the circuit of FIG. 4 during a measurement phase;

FIG. 8 illustrates the circuit of FIG. 4 during an A/D conversion phase;

FIG. 9 is a flow diagram illustrating the processing steps performed by the electronic circuit of FIG. 4 according to the present invention;

FIG. 10 illustrates another example of an electronic circuit according to the present invention connected to a capacitive acceleration sensor; and

FIG. 11 is a timing diagram illustrating the control signal sequences used in the circuit of FIG. 10.

### DETAILED DESCRIPTION

Referring to FIG. 2, a schematic illustration of an electronic circuit 12 according to the present invention is provided, in this example the front-end circuitry for an analogue sensor 13. The circuitry 12 is, in the present example, implemented in a mobile telephone, on a single chip using 130 nm complimentary metal-oxide-semiconductor (CMOS) integration technology.

The front-end circuitry 12 includes analogue signal processing circuitry 14 connected to the output of the sensor 13. In the present example, the analogue signal processing circuitry 14 includes an amplifier arranged to amplify the analogue input signal received from the sensor 13, and an analogue storage device to store the input signal. The analogue signal processing circuitry 14 is also configured, in the present example, to adjust the test voltages used in the analogue sensor 13 when taking measurements. However, alternative configurations of the analogue signal processing circuitry 14 can be used, as may be required according to the particular application of the electronic circuit 12 and/or the specific type of sensor 13. For instance, the amplifier and/or analogue storage device may be omitted in the case that such functions are not required in the analogue signal processing circuitry 14.

The output of the analogue signal processing circuitry 14 is connected to the input of an analogue to digital (A/D) converter 15, the output of which is, in turn, connected to an output terminal 16 of the front-end circuitry 12 and to the write-input of a digital storage device 17, in this example random access memory (RAM) 17. An output of the RAM 17 is connected to a digital to analogue (D/A) converter 18. The output of the D/A converter 18 is connected to a feedback path providing feedback to the analogue signal processing circuitry 14.

A controller 19 provides timing control signals for controlling the components of the front-end circuitry 12.

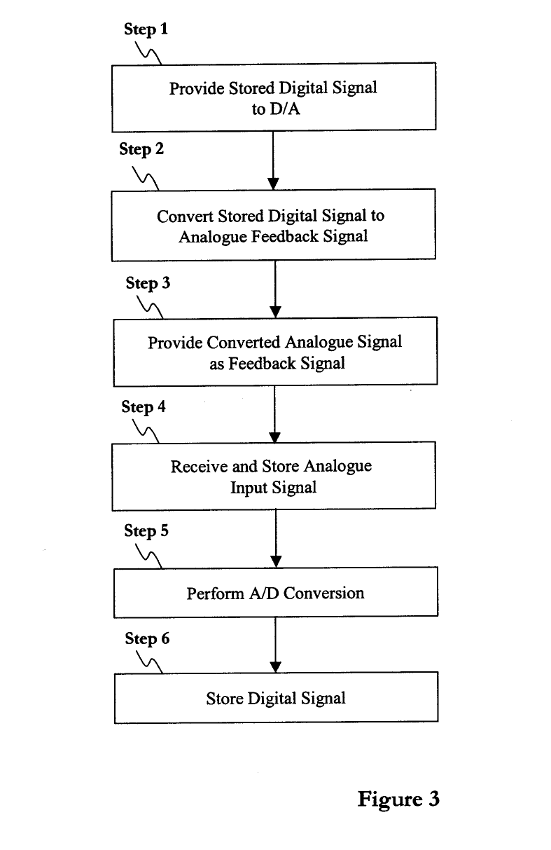

Operation of the front-end circuitry 12 of FIG. 2 will now be described with reference to FIG. 3. At the start of a first sampling period, digital feedback data stored in the RAM 17 is provided to the D/A converter 18 (step 1). The D/A converter 18 converts the digital feedback data to an analogue feedback signal (step 2), which is provided as feedback to the analogue signal processing circuitry 14 (step 3). For instance, in the present example, the analogue feedback signal is used to adjust test voltages applied to the sensor 13 so that an accurate measurement can be obtained. However, in alternative examples of the invention, the analogue feedback signal need not be used in this manner, but could alternatively be used solely within the electronic circuit 12, for instance for improving the dynamic performance of the circuit 12.

The analogue signal processing circuitry 14 stores the analogue input signal received from the sensor 13 (step 4) and provides the stored analogue signal to the A/D converter 15, which converts the analogue signal into a digital data signal (step 5). The digital data signal is, in turn, provided from the output of the A/D converter 15 to both the output terminal 16 of the electronic circuit 12 and to the RAM 17. The digital data signal provided at the output terminal 16 of the circuit 12 can be applied to further circuitry (not illustrated) for processing as may be required according to the particular application of the sensor 13. For instance, the digital signal can be analysed to extract particular information or may be compressed and stored in memory for processing at a later time.

The RAM 17 stores the digital data signal (step 6) until the start of a subsequent sampling period. In the present example, the RAM 17 stores the digital signal until the start of the sampling period immediately following the sampling period in which the digital data signal is stored, although the RAM 17 can be arranged to store the digital signal for longer periods and/or to store multiple digital signals.

The steps described above with reference to FIG. 3 are performed for each sampling period. Since the data processing performed in each sampling period starts with a digital to analogue conversion and ends with an analogue to digital conversion, such processing can be performed for a fraction of the sampling period, with feedback data held in the digital domain for the remainder of the sampling period. This enables the sampling frequency of the electronic circuit 12 to be reduced, thus minimising power consumption, without leakage currents in the analogue storage components of the CMOS circuit causing inaccuracies.

For instance, the sampling frequency in the example of FIG. 2 can be reduced to less than 1 kHz without the adverse effects otherwise caused by leakage currents. The control circuitry can be configured to turn-off the analogue components of the circuit 12, such as the components of the analogue signal processing circuitry 14, when they are not in use. Accordingly, such components can be operated for only a small fraction of each sampling period, thus resulting in a large saving in power consumption.

Additional circuitry can also be implemented in the electronic circuit 12 of FIG. 2 to enable control voltages to be used to adjust the analogue signal, for example to reduce noise. Such control voltages can also be used to provide an initial value for the feedback signal. The D/A-converter 18 can, for instance, be loaded with predetermined data, for instance an initial value for a previous sensor measurement and/or with temperature dependent tuning parameters or other error cancelling parameters. In this case, additional memory can be provided, for instance additional RAM, for storing the predetermined data, or the RAM 17 provided in the circuit of FIG. 2 can be used to store the predetermined data and to provide the data to the D/A-converter 18 when required. The D/A-converter 18 can alternatively or additionally be used to provide multiple feedback signals, or to provide other control signals to the analogue circuit.

Digital signal processing (DSP) circuitry (not shown) can also be provided in the front-end circuit of FIG. 2, either in addition to or in place of the digital storage device 17. For instance, DSP circuitry can be provided between the RAM 17 and the D/A-converter 18. Such circuitry can, for instance, perform digital filtering or other digital processing steps as may be required depending on the particular application.

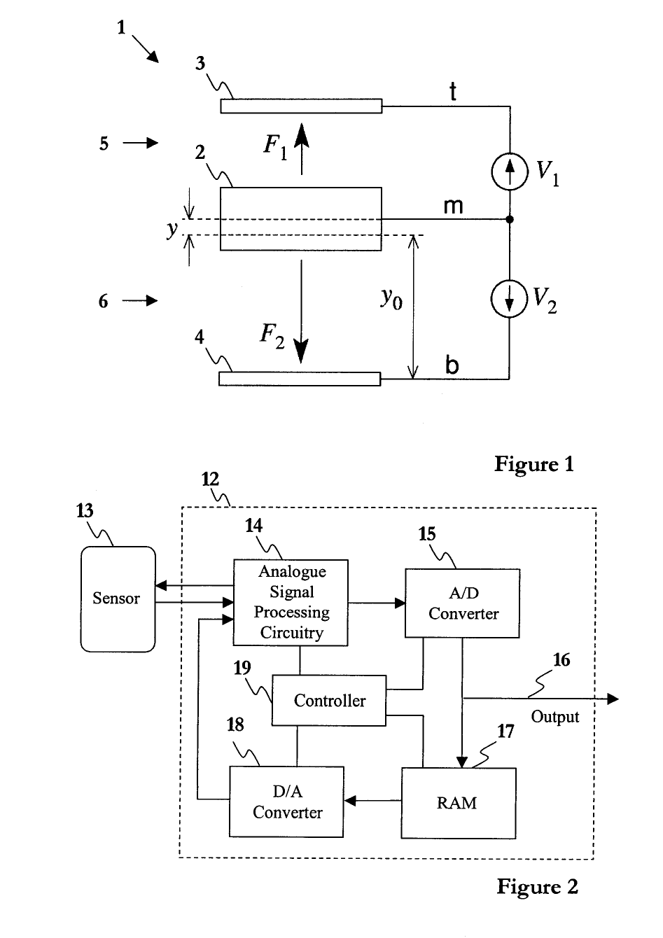

The sensor 13 used with the front-end circuitry in the example of FIG. 2 can, for instance, be a capacitive acceleration sensor as illustrated in FIG. 1 having a single pair of capacitors. Alternatively, the sensor 13 can include two, three or more such capacitive acceleration sensors, therefore having two, three or more capacitor pairs, for instance for measuring acceleration in 2- or 3-dimensions. Other capacitive sensors can also be used with the circuit of FIG. 2, either in addition to or in place of the acceleration sensor(s), for instance for additionally measuring pressure, humidity etc.

In cases in which multiple sensors are used with the circuit of FIG. 2, a multiplexer (not shown) can be implemented at the input of the circuit for selecting one sensor at a time, such that the circuit can perform a measurement for each sensor in turn in a specific measurement sequence. In this case, other components of the circuit, such as the digital storage device 17 and D/A converter 18, can be adapted to perform sensor multiplexing such that their operation is based on the particular sensor measurement that is being performed. For instance, the steps described above with reference to FIG. 3 can, in this case, be performed in each sampling period for each sensor, or can be performed for a different single sensor in each sampling period according to a measurement sequence.

Although in the example of FIG. 2, the circuitry 12 is provided as the front-end circuitry for an analogue sensor 13, the invention is not limited to this. Alternatively the invention can be used in other applications in which an analogue signal is to be periodically sampled using analogue components and in which feedback is required.

Furthermore, although the example of FIG. 2 is implemented using 130 nm CMOS integration technology, the invention is not limited to this, but could have the same or further advantages when applied to circuits implemented using other integration technologies, in particular those denser than 130 nm such as 90 nm, silicon on insulator (SOI) technologies, or other types of integrated circuit that suffer from leakage currents.

Also, although the example of FIG. 2 is described as being implemented as part of a mobile telephone, the invention is not limited to this. The invention can also be applied to other devices or arrangements, for instance alternative portable devices such as personal digital assistants (PDAs), global positioning system (GPS) devices or in laptop computers.

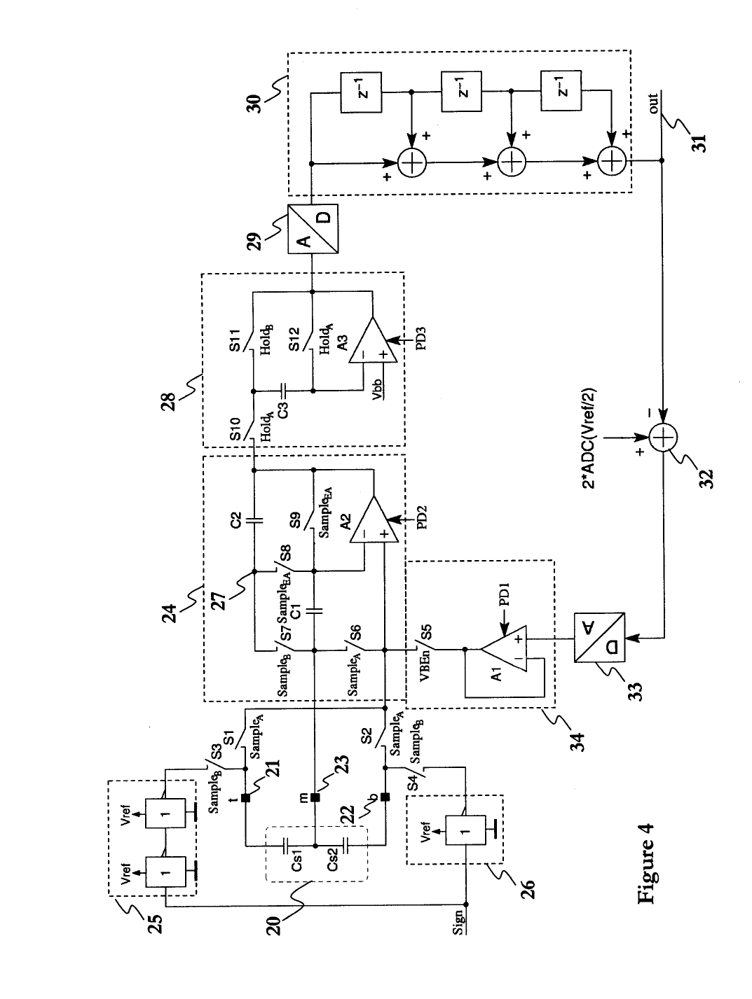

FIG. 4 illustrates a further example of an electronic circuit according to the present invention, in this case a mixed-mode self-balancing bridge circuit for use with a capacitive acceleration sensor 20, implemented on a single CMOS chip. The electronic circuit of FIG. 4 is implemented in a mobile telephone in which the capacitive acceleration sensor 20 is also implemented.

Referring to FIG. 4, the capacitive acceleration sensor 20 has first and second electrodes 21, 22, also referred to as top and bottom electrodes t, b, connected to the outer capacitor plates of the respective first and second sensor capacitors Cs1, Cs2 of the acceleration sensor 20. A third electrode 23, also referred to as a middle electrode m, is connected to the mass of the acceleration sensor 20.

The first electrode 21 is selectively connected, via a first switch S1, to the non-inverting input of an operational amplifier A2 of a charge amplification circuit 24. The second electrode 22 is selectively connected to the non-inverting input of the operational amplifier A2 via a second switch S2. The first electrode 21 is also selectively connected, via a third switch S3, to a voltage supply terminal 25 for supplying a voltage Vref with respect to a common ground or reference terminal 26, and the second electrode 22 is connected, via a fourth switch S4, to the ground terminal 26. The third electrode 23 is connected, via a first capacitor C1, to an inverting input of the operational amplifier A2 of the charge amplification circuit 24.

The charge amplification circuit 24 is generally formed as a correlated double sampling charge amplifier arrangement with a second capacitor C2 and the first capacitor C1 respectively selectively connected in series between the output of the operational amplifier A2 and its inverting input, according to the on/off condition of a seventh switch S7 arranged between the first and second capacitors C1, C2. An eighth switch S8 selectively connects a node 27 between the second capacitor C2 and the seventh switch S7 to the inverting input of the operational amplifier A2. A ninth switch S9 selectively connects the output of the operational amplifier A2 directly to its input. A sixth switch S6 selectively connects the non-inverting input of the operational amplifier A2 to the third electrode 23, and accordingly to the first and second electrodes 21, 22, according to the on/off conditions of switches S1 and S2 respectively.

The output of the operational amplifier A2 of the charge amplification circuit 24 is selectively connected to the inverting input of an operational amplifier A3 of a sample and hold arrangement 28, via a series arrangement of a tenth switch S10 and a third capacitor C3. A voltage Vbb is applied to the non-inverting input of the operational amplifier A3 of the sample and hold arrangement 28. An eleventh switch S11 selectively connects the third capacitor C3 into a feedback loop of the operational amplifier A3, between its output and its inverting input. A twelfth switch S12 selectively connects the output of the operational amplifier A3 of the sample and hold arrangement 28 directly to its inverting input.

The output of the operational amplifier A3 of the sample and hold arrangement 28 is connected to the input of an A/D converter 29, the output of which is connected to the input of a finite impulse response (FIR) filter 30. The FIR filter 30 is formed of three cascaded filter stages in the present example, each providing an output that has a delay of one sampling period with respect to its input, and the output of each being respectively added to the FIR filter input signal received from the A/D converter 29. However, different arrangements of FIR filter or an FIR filter having an alternative numbers of stages and different summing weights can be used. Alternative filters, such as an infinite impulse response (IIR) filter can also be used.

The output of the FIR filter 30 is connected to an output terminal 31 of the electronic circuit and to the input of an inverting arrangement 32. The inverting arrangement 32 comprises a summing circuit in which the output of the FIR filter 30 is applied to a subtracting input and a digital signal having a value of twice the analogue to digital conversion of the voltage level Vref/2 is applied to an adding input. Other arrangements can alternatively be used to invert the digital signal supplied from the FIR filter 30.

The output of the inverting arrangement 32 is connected to the input of a D/A converter 33. The output of the D/A converter 33 is connected to the non-inverting input of an operational amplifier A1 of a buffer arrangement 34. The output of the operational amplifier A1 of the buffer arrangement 34 is selectively connected to the non-inverting input of the operational amplifier A2 of the charge amplification circuit 24, via a fifth switch S5.

Control circuitry (not shown) is also provided for controlling the components of the electronic circuit of FIG. 4. For instance, in use, the three operational amplifiers A1, A2, A3 are individually powered, when they are required to operate, according to first, second and third power-down signals PD1, PD2 and PD3 applied to each respective amplifier A1, A2, A3, provided by the control circuitry.

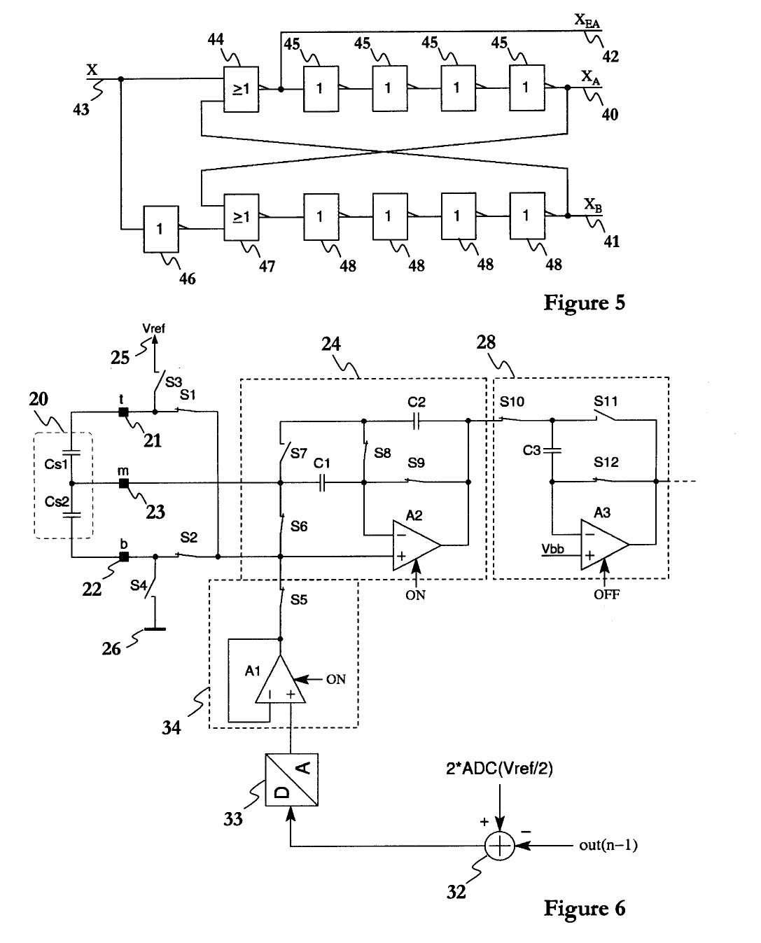

The analogue parts of the electronic circuit of FIG. 4, namely the charge amplification circuit 24 and sample and hold arrangement 28, are implemented as switched capacitor arrangements. Accordingly, the first to twelfth analogue switches S1 to S12 are preferably controlled with non-overlapping control signals ‘sample’, and ‘hold’, generated, in the present example, using control signal generating circuits implemented using an application specific integrated circuit (ASIC) forming part of the control circuitry. An example of a control signal generating circuit is illustrated in FIG. 5.

Referring to FIG. 5, output signals X_{A}, X_{B} and X_{EA} are generated at first, second and third output terminals 40, 41, 42 respectively of the control signal generating circuit in response to a synchronous control signal X being applied at an input terminal 43. The control signal generating circuit includes a first NOR gate 44 having first and second inputs to which the input terminal 43 and the second output terminal (at which X_{B} is provided) are respectively connected. The output of the first NOR gate 44 is connected to the third output terminal 42 (at which X_{EA} is provided) and to the input of a first group of four NOT gates 45 connected in series. The output of the first group of NOT gates is connected to the first output terminal 40 (at which X_{A} is provided).

The control signal generating circuit also includes a single inverter 46 having an input connected to the input terminal 43. A second NOR gate 47 has first and second inputs, to a first of which the output of the single inverter 46 is connected and to the second of which the first output terminal (at which X_{A} is provided) is connected. The output of the second NOR gate 47 is connected to the input of a second group of four NOT gates 48 connected in series. The output of the second group of NOT gates 48 is connected to the second output terminal 41 (at which X_{B} is provided).

The control signal generating circuit of FIG. 5 accordingly, in use, generates non-overlapping output signals X_{A} and X_{B} as well as a third signal, X_{EA}, which is a slightly earlier version of X_{A} used widely in SC-circuits to realize so called bottom-plate sampling technique to lower non-idealities in switching. Therefore, when, for example, switch control signal ‘Sample’ is applied as input signal ‘X’ to the signal generating circuit of FIG. 5, when ‘Sample’ has logic value ‘0’, the first, second and sixth switches S1, S2 and S6, controlled by signal Sample_{A}, conduct, as well as the eighth and ninth switches S8, S9, controlled by signal Sample_{EA}. However, the third, fourth and seventh switches S3, S4, S7, controlled by signal Sample_{B}, do not conduct. When Sample rises to logic value ‘1’, signal Sample_{EA} firstly goes down and therefore the eighth and ninth switches S8 and S9 stop conducting, after which signal Sample_{A} goes down and therefore the first, second and sixth switches S1, S2 and S6 stop conducting. Finally, signal Sample_{B} rises and the third, fourth and seventh switches S3, S4 and S7 start to conduct. Equivalent output signals would be generated for the tenth, eleventh and twelfth switches S10, S11, S12 controlled by the control signals Hold_{A} and Hold_{B}.

Other control signals, VBEn, PD1, PD2 and PD3, are normal synchronous control signals without any need for non-overlapping sequence generation.

The operation of the circuit of FIG. 4, under the control of the control circuitry, will now be described in detail with reference to FIGS. 6, 7, 8 and 9.

### Initialisation Phase

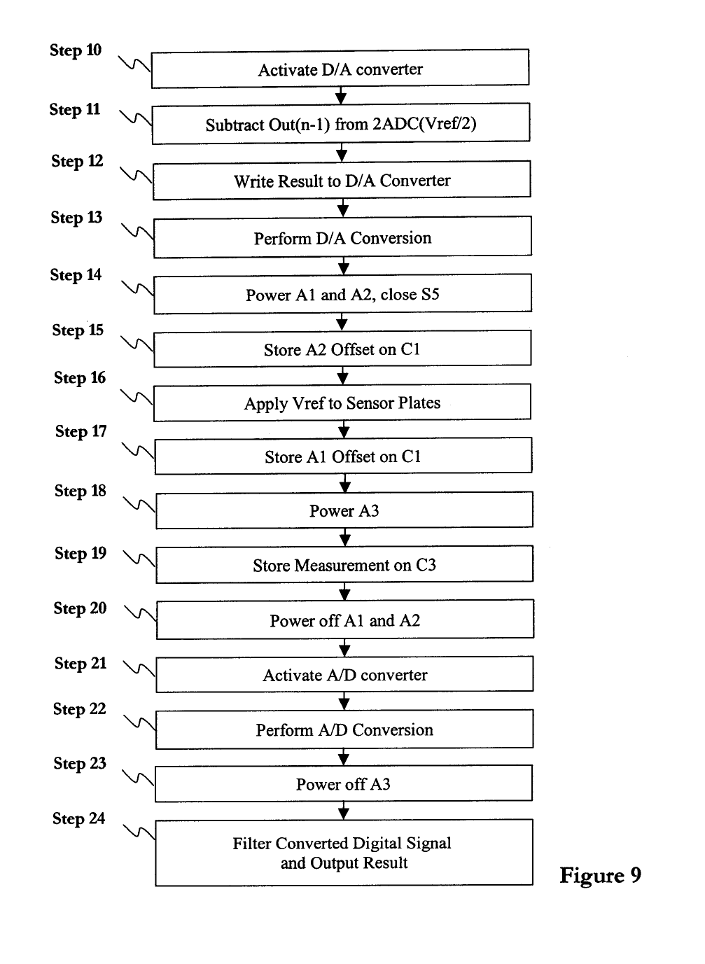

Referring to FIGS. 6 and 9, a measurement sequence starts by activating the D/A converter 33 (step 10) using the control circuitry (not illustrated). Instead of converting the last A/D-converted and digitally filtered output word out(n−1) from the FIR filter 30 back into the analogue domain with the D/A-converter 34, the signal is firstly inverted in order to achieve negative feedback instead of positive feedback that would saturate the feedback loop to either the minimum or maximum operational amplifier supply rails.

In many cases, the A/D- and D/A-conversion full scales of A/D and D/A converters used in circuits such as that of FIG. 4 do not correspond exactly to Vref, and therefore inverting the signal in the digital domain is preferable. This is performed in the present example by subtracting out(n−1) from twice the A/D-conversion result of Vref/2 (i.e. 2 ADC(Vref/2)) using the summing circuit 32 (step 11). Since the A/D-conversion full scale of A/D converters implemented in the circuit is generally lower than Vref, it is preferable to perform the A/D-conversion of Vref/2 and multiply the result by two in the digital domain. If this constant does not correspond to exactly Vref/2, a residual electric force will be present when the voltage bias is applied to the sensor capacitor pair Cs1, Cs2. However, such forces are in most cases negligible.

The resulting digital data is provided (step 12) to the D/A converter 34 from the summing arrangement 32, which, in turn, receives the output of the FIR filter 30 (see FIG. 4). Digital conversion is then performed by the D/A converter 33 (step 13).

Following this, the amplifier A1 of the buffer arrangement 34 and the amplifier A2 of the charge amplifier arrangement 24 are powered on by power signals PD1 and PD2 (step 14), but the amplifier A3 of the sample and hold arrangement is left in sleep mode. In this phase, switch control signal VBEn (controlling the fifth switch S5) is set to logic level ‘1’, while both control signals ‘Sample’ and ‘Hold’ are still low (i.e. logic level ‘0’). Simultaneously, the offset voltage of the operational amplifier A2 of the charge amplification circuit 24 is stored on the first capacitor C1 (step 15).

The amplifier A1 of the buffer arrangement 34 is provided to ensure that the off-chip parasitic capacitances at the third electrode 23 of the capacitive acceleration sensor 20 will be charged to the desired voltage while the sensor capacitors Cs1 and Cs2 are shorted so that no electrical force will affect the mass of the accelerometer 20.

### Measurement Phase

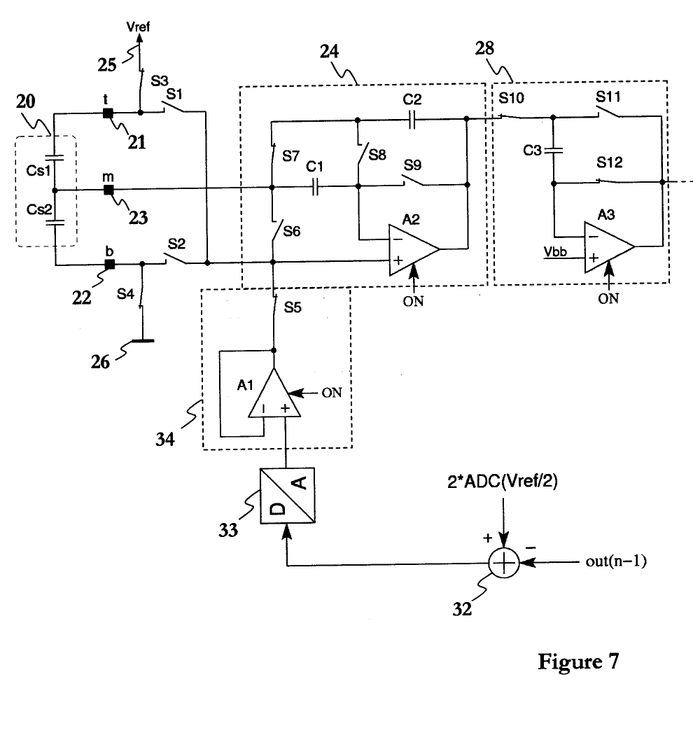

After the voltage at the third (middle) electrode 23 of the acceleration sensor 20 is settled, charge amplification can be performed by applying a bias voltage (Vref) across the first electrode 21 (top plate) and second electrode 22 (bottom plate) of the sensor 20, as shown in FIG. 7 (step 16). Then, if the centre mass of the sensor 20 has changed position since the last measurement was performed, a change in capacitor charges results in an output voltage V_{O2} at the amplifier A2 output

V_{O2}=V_{DAC}−C2·ΔQ (5)

where V_{DAC} is the voltage at the output of the D/A converter 33, ΔQ is the change in charge at the third electrode 23 of the sensor 20 and C2 is the capacitance of the second capacitor C2 of the charge amplification circuit 24. The offset voltage of amplifier A1 is stored in capacitor C1 so that it cancels out in the output voltage V_{O2} (step 17).

The amplifier A3 of the sample and hold arrangement 28 is also activated in the measurement phase (step 18) and the output voltage V_{O2} of the amplifier of the charge amplification circuit 24 is stored on the third capacitor C3 for use in the A/D conversion phase (step 19).

The reference voltage Vbb applied to the non-inverting input of the amplifier A3 of the sample and hold arrangement is selected to provide a voltage level in which the amplifier input stage works well and the voltage level should be stable during the activity period. For example the voltage level in the present example is set to Vref/2. In alternative examples, a diode-connected NMOS-transistor can be used. The absolute value of Vbb is, in general, not critical since the circuit is arranged to cancel it out.

### A/D Conversion Phase

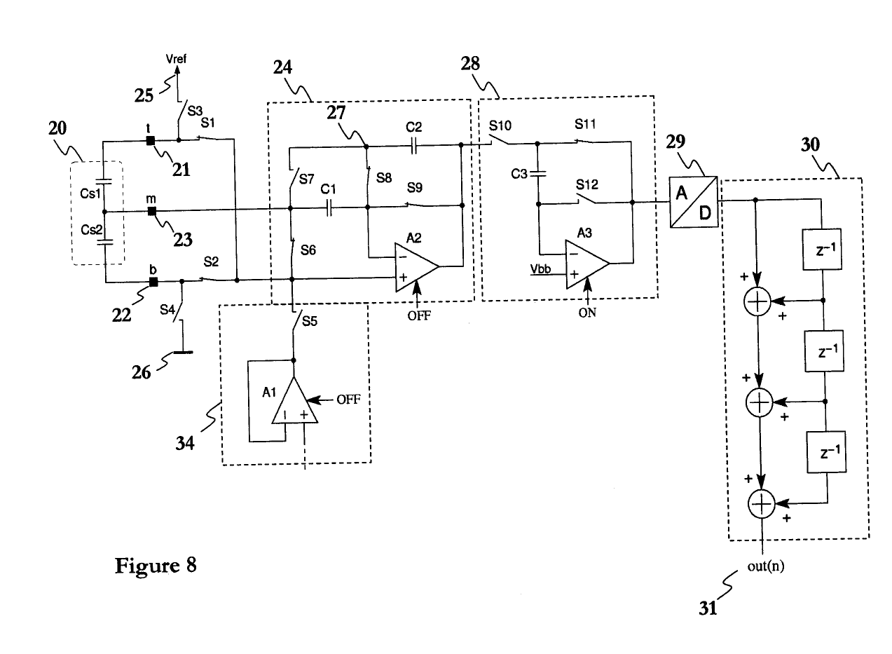

Referring to FIGS. 8 and 9, in the A/D-conversion phase, once the tenth switch S10 is not conducting, the amplifiers A1 and A2 of both the buffer arrangement 34 and the charge amplification circuit 24 can be powered off (step 20), thus saving a significant amount of power. The A/D converter 29 is then activated (step 21) and the A/D-conversion is performed (step 22). Once the A/D conversion is complete, the amplifier A3 of the sample and hold arrangement 28 can also be powered off (step 23) along with the rest of the analogue circuitry, with the exception of a main clock generator for each of the analogue and digital blocks.

The A/D converted data is fed to the FIR-filter 30 from the A/D converter 29 and filtered (step 24), the resulting output of the filter 30 at the output electrode 31 is the measurement output, which can be further processed as requires, for instance to detect application specific gestures etc. The measurement sampling frequency is set by a timer, which keeps the digital part in hold and the analogue part powered off until the whole sampling period

$$t = \frac{1}{{f}_{s}} \qquad ( 5 )$$

is elapsed, where fₛ is the sampling frequency, and after that the next measurement cycle is started.

The clock frequency of the digital control circuitry can be set to be high enough so that the signals controlling power-up of the amplifiers A1, A2 and A3 can be realized with synchronous control logic and such that the A/D-conversion time can be kept relatively low. Furthermore, the non-overlapping timing signals for switches S1 to S12 (Sample_{A}, Sample_{B}, Sample_{EA}, Hold_{A} and Hold_{B}) can, rather than being generated using the asynchronous circuit of FIG. 5, alternatively be generated in synchronous logic. However, in this case, higher clock frequencies may be required resulting in higher power consumption of the digital components.

The analogue switch on- and off-times are selected so that they are long enough to ensure power efficient amplifier realization, since shorter amplifier settling times require higher amplifier current consumption, yet short enough to keep the errors caused by leakage currents lower than the A/D-converter resolution, thus enabling adequate accuracy with modern deep-submicron CMOS processes.

Normally, the digital clock frequency is arranged to be in the range of few megahertz and the analogue switch on- and off-times are in the range of one or two microseconds. Accordingly, the duration of one measurement, including D/A-conversion, sensor capacitance sampling and amplification and A/D-conversion, is in the range of tens of microseconds. Since, in many applications, sampling rates for capacitive accelerometers can be set to below 1 kHz, the analogue circuitry can be powered on only for 1% of the whole sampling period, leading to very low average current and therefore power consumption.

The amplifiers A1 and A2 of the buffer arrangement 34 and the charge amplification arrangement 24 can require relatively high current consumption in order to maintain stable operation with large off-chip parasitic capacitances connected to the third electrode 23 of the sensor 20. However, the amplifier A3 of the sample and hold arrangement 28 drives on-chip loads thus enabling a lower current consumption. Accordingly, since amplifiers A1 and A2 can be turned off while the measurement is held by amplifier A3, current and therefore power consumption can be reduced, although using this separate sample-and-hold amplifier (A3) increases silicon area.

While the specific arrangements of FIGS. 2 and 4 have been described as having separate sample and hold arrangements 14, 28, the output measurements from the sensors 13, 20 could be stored in alternative ways, for instance held by the second capacitor C2 and amplifier A2 of the charge amplifier circuit 24. However, any signal disturbances at the third electrode 23 could affect the A/D-conversion in such an arrangement.

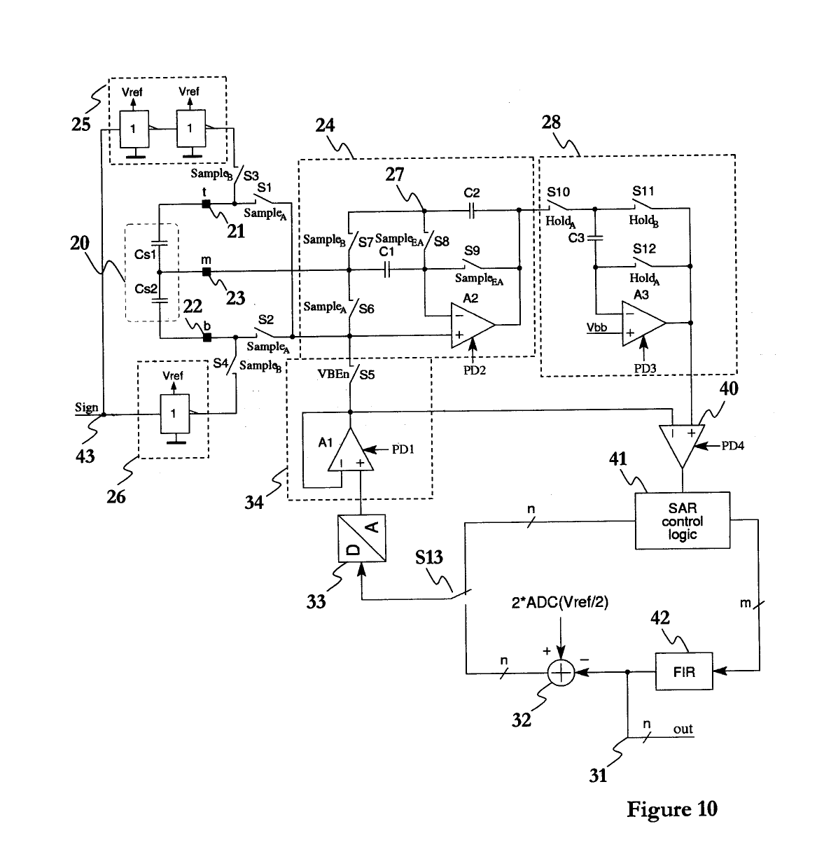

FIG. 10 illustrates a further example of an electronic circuit, in this case a mixed-mode self-balancing bridge circuit, according to the present invention. In this arrangement, the acceleration sensor 20 and its voltage supply circuitry 25, 26, the charge amplification circuitry 24, sample and hold arrangement 28, summing circuit 32, D/A converter 33 and buffer arrangement 34 are equivalent to those described with reference to FIG. 4. However, in order to minimize silicon area, the A/D-converter is realized using the successive approximation principle. In particular, the A/D-converter is formed using a successive approximation A/D converter comprising the D/A-converter 33, a comparator 40, successive approximation register (SAR) control logic 41 and a digital FIR-filter 42. Therefore, the D/A-converter 33 is not only used in the digital to analogue conversion required to provide the analogue feedback signal, but is also reused as a building block of the successive approximation A/D converter, according to the on-off condition of a thirteenth switch S13.

While, during D/A-conversion, whether for providing feedback to the charge amplification circuitry 24 or as part of the SAR A/D converter operation, the voltage buffer 34 is turned on for the whole analogue activity period, the comparator 40, however, need only be turned on during A/D-conversions. For m-bit conversion, the successive approximation converter requires m conversion cycles. The digital FIR-filter 42 performs interpolation resulting in an n-bit output from an m-bit input, where n>m.

In the circuit of FIG. 10, although the voltage offsets of amplifiers A2 and A3 can be cancelled out using the correlated double sampling technique, the output offset voltage of the voltage buffer amplifier A1 is not cancelled in the offset cancelling technique. Additionally, there can be other DC-voltage error sources such as contact potentials in the accelerometer sensors. This can result in a residual electric force being present when the voltage bias is applied to the sensor capacitor pair Cs1, Cs2. Such forces are in many cases negligible, but they can be further attenuated by alternating the polarity of the bias voltage applied to the sensor 20 periodically using an additional signal ‘Sign’ applied at an input terminal 43 of the electronic circuit, to improve measurement accuracy. The circuit is referred to as operating in a chopping mode, in which every odd measurement cycle has an opposite bias voltage polarity to every even measurement cycle. Accordingly, the differences of the output in even and odd sampling periods caused by DC-non-idealities at least partially cancel out over several sampling periods, including offset voltages and 1/f-noise of the voltage buffer arrangement 34.

Similarly, in fast transients where the measurement circuit in not fast enough to follow sensor mass displacement so that charge imbalance occurs, the resulting electrical error forces have opposite directions in even and odd measurement instances thus partially cancelling out the effect of the error forces.

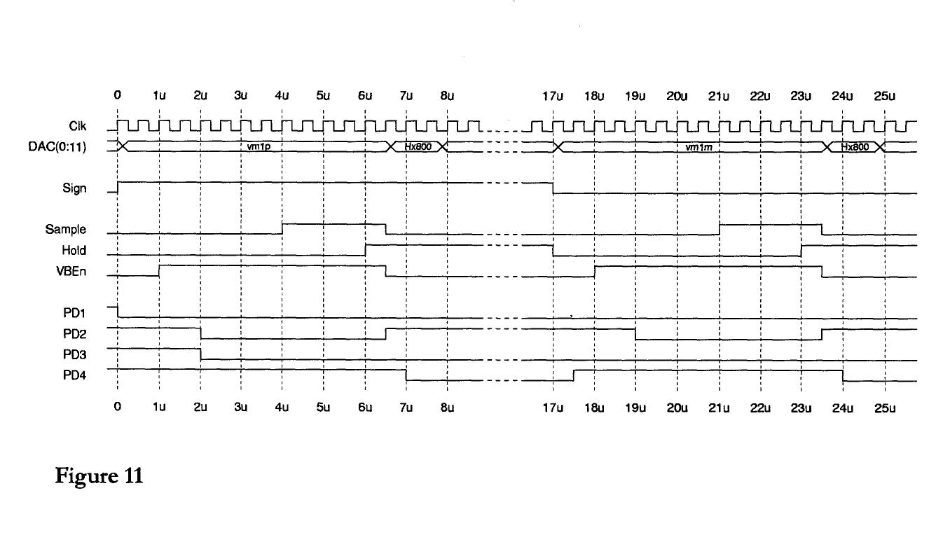

The control sequences for the mixed-mode self-balancing bridge circuit of FIG. 10 are illustrated in FIG. 11.

A 2 MHz main clock is assumed for the synchronous logic generating the control signals, resulting in a 0.51 is timing resolution. Additionally, a 12-bit D/A-converter and 10-bit successive approximation A/D-conversion with a 1 μs conversion cycle is assumed, and therefore the m-bit signal of FIG. 10 comprises a 10-bit signal and the n-bit signal of FIG. 10 comprises 12-bits.

The measurement cycle starts by loading the appropriate data (vmlp) into the D/A-converter 33. At the same time the bias voltage polarity control (Sign) is set to ‘1’ and the amplifier A1 is activated by clearing power-down signal PD1 to ‘0’. The output of A1 of the buffer arrangement 34 is assumed to settle, without off-chip load, in 1 μs, and after that the analogue switch S5 is activated to connect the output of amplifier A1 to the off-chip sensor electrode 23.

Both amplifier A2 of the charge amplification circuit 24 and A3 of the sample and hold arrangement are activated 2 μs after the measurement sequence starts. The sample-and-hold amplifier A3 could be turned off for yet another 2 μs but then the start-up transients may affect the charge amplification accuracy and thus the resulting minor increase in average power consumption is generally preferable.

Both amplifiers A2 and A3 are assumed to settle in 2 μs and thus both the error-sampling phase (from the falling edge of signal PD2 to rising edge of signal ‘Sample’) and the charge amplification phase (from the rising edge of signal ‘Sample’ to the rising edge of signal ‘Hold’) last for 2 μs.

The ‘Hold’ signal raises 0.5 μs before the ‘Sample’ signal falls to ensure that there are no glitches at the output of amplifier A2 when switches S10 and S12 are opened. At 6.5 μs, the sample-and-hold amplifier A3 has a valid signal stored at the third capacitor C3 and there is no connection to the output of amplifier A2 and thus A2 can be powered off. Since the amplifier A1 of the voltage buffer arrangement 34 is required in A/D-conversion, it remains powered on.

Signal PD4 is cleared to ‘0’, which turns on the comparator 40, and A/D-conversion takes 10 μs to complete so that at 17 μs the measurement with opposite sensor bias voltage can start. This measurement cycle is almost identical to the first one; the Sign-signal is changed from ‘1’ to ‘0’ at the start of the second measurement cycle and amplifiers A1 and A3 need not to be turned on since they were not powered off during the first measurement cycle. The sample-and-hold amplifier A3 could be turned off for a short instant in the start of the second measurement cycle but the resulting power saving is minimal and may be wasted in the power-on transient, not to mention possible disturbances to A1 and A2.

In the case of a 1-axis accelerometer, there is only one capacitor pair Cs1, Cs2.

At 34 μs, the measurement has been performed with both bias voltage polarities and enough data is gathered so that one accurate sample can be calculated with digital post-processing. Therefore, if the required sampling rate to gather 1-axis acceleration data is 1 kHz, the analogue part of the mixed-mode self-balancing bridge is on only for 3.4% of the actual sampling period and thus the average current consumption of the analogue parts of the circuit can be lowered almost to 3.4% of the active current consumption of the analogue parts. The powering on and off transients and leakage current in modern CMOS processes will slightly limit the power saving. In addition to this, the sensor front-end requires a 2 MHz clock generator, which cannot be turned off along with other analogue blocks.

The voltage reference Vref can be a passively filtered external voltage available in the system but, in certain cases, this reference voltage may be generated with an on-chip voltage regulator that requires longer turn on and off times than other analogue circuit blocks. When an on-chip Vref regulator is used, most likely an on-chip voltage reference (Bandgap-reference) is also required thus increasing the total current consumption. However, this reference voltage is required also in the conventional sensor interface and, in the case of mixed-mode self balancing bridge, it is possible to turn these references off while the analogue part of the sensor interface is powered off.

Applying the above described measurement principles to sensors with 2 or more axes and thus 2 or more capacitor pairs is straight-forward. With multiple capacitor pairs, the third, or middle electrode (m) is common for all capacitor pairs and the top (t) and bottom (b) electrodes are individually controlled with analogue switches so that all capacitances remain shorted except during the Sample_{B} period when the voltage bias is applied the a particular capacitor pair that are to be measured.

Therefore, for N pairs of sensor capacitors, the active measurement time is N*34 μs leading to approximately 10% activity with 3 sensor capacitor pairs with 1 kHz sampling frequency.

Based on numerical simulations, the mixed-mode self-balancing bridge circuits of FIGS. 4 and 10 gain approximately 1 bit every time the oversampling ratio is doubled, and therefore with moderate oversampling ratios a significant increase in sensor resolution is achieved.

A register-programmable digital counter can be used to control the sampling rate to almost any desired value without any hardware changes in clock generators etc. The mixed-mode self balancing bridge circuits of FIGS. 4 and 10 can be fabricated with modern deep submicron CMOS-technology used to implement application specific gesture recognition and other post-processing. Such circuits can operates with all capacitive sensor elements available on the market, these having different numbers of axes and different mechanical realizations, without requiring complex modifications to the sensor front-end or additional silicon area usage.

The proposed mixed-mode self-balancing bridge circuits can be used to perform a one-shot measurement by using an educated guess as the bridge balance state and the bias voltage chopping. However, in start-up, conventional arrangements, such as normal sigma-delta modulators, require a significant amount of time before output data can be considered valid.

The proposed mixed-mode self-balancing bridge provides enough resolution for each application in question with minimal power consumption and very small silicon area. Unlike other self-balancing bridge realizations, this realization scales well with CMOS-integration technology.

The digital functionality of the above described electronic circuits, for instance the FIR filter arrangements 30, 42 of FIGS. 4 and 10, can be implemented using reconfigurable circuit technology, rather than using a fixed arrangement, so as to improve the flexibility of the circuits for different specific applications. Furthermore, both the analogue and digital components can be provided as basic, re-usable blocks. In this way, the resulting discrete component blocks can be selectively incorporated and/or configured to provide application-specific front-end sensor circuitry implementations.

It should be realised that the foregoing examples should not be construed as limiting. Other variations and modifications will be apparent to persons skilled in the art upon reading the present application. Such variations and modifications extend to features already known in the field, which are suitable for replacing the features described herein, and all functionally equivalent features thereof. Moreover, the disclosure of the present application should be understood to include any novel features or any novel combination of features either explicitly or implicitly disclosed herein or any generalisation thereof and during the prosecution of the present application or of any application derived therefrom, new claims may be formulated to cover any such features and/or combination of such features.

1. A method comprising:
using an analog storage device of an electronic circuit to store an analog input signal;
using an analog to digital converter of the electronic circuit to convert the stored analog input signal into a digital signal and storing the digital signal;
using a digital to analog converter of the electronic circuit to convert the stored digital signal into an analog feedback signal; and
providing feedback in the electronic circuit using the analog feedback signal.

2. A method according to claim 1, further comprising the step of sampling the analog input signal, wherein storing the analog input signal comprises storing the sampled analog input signal.

3. A method according to claim 2, wherein storing the analog input signal, converting the stored analog input signal into a digital signal and storing the digital signal are performed in a first sampling period.

4. (canceled)

5. A method according to claim 3, further comprising performing, in each sampling period n of a plurality of sampling periods occurring after the first a first sampling period:
converting the digital signal stored in the (n−1)^{th} sampling period into an analog feedback signal and providing feedback in the electronic circuit using the analog feedback signal;
storing the analog input signal using the analog storage device;
converting the analog input signal stored in the n^{th} sampling period into a digital signal; and
storing the digital signal obtained in the n^{th} sampling period.

6. A method according to claim 5, further comprising performing the method steps performed in each of the plurality of sampling periods in a fraction of the respective sampling period.

7. (canceled)

8. A method according to claim 5, wherein the plurality of sampling periods occur periodically at a sampling frequency of less than 1 kHz.

9. A method according to claim 1, further comprising providing the digital signal as an output of the electronic circuit.

10-11. (canceled)

12. A method according to claim 1, further comprising storing an error signal indicative of errors in the electronic circuit and adjusting said analog input signal using said stored error signal.

13. A method according to claim 1, further comprising:
converting the stored analog input signal into a digital signal using the digital to analog converter in a successive approximation analog to digital converter arrangement.

14. A method according to claim 1, further comprising:
providing the digital to analog converter with predetermined data and data; wherein of using the digital to analog converter to convert the stored digital signal into an analog feedback signal comprises using the digital to analog converter to convert the stored digital signal and the predetermined data into the analog feedback signal.

15. An electronic circuit comprising:
an analog storage device for storing an analog input signal;
an analog to digital converter arranged to convert an analog input signal stored by the analog storage device into a digital signal;
a digital storage device arranged to store a digital signal provided by the analog to digital converter; and
a digital to analog converter arranged to convert a digital signal stored at the digital storage device into an analog feedback signal for providing feedback in the electronic circuit.

16. An electronic circuit according to claim 15, wherein the analog storage device is implemented using a CMOS integration technology.

17. (canceled)

18. An electronic circuit according to claim 15, further comprising a control unit arranged to power off the analog storage device during a period when it is not required to store the analog input signal.

19-21. (canceled)

22. An electronic circuit according to claim 15, arranged to operate as a self-balancing bridge.

23. An electronic circuit according to claim 15, further comprising:
an error storage device storing an error signal indicative of errors in the electronic circuit; and
error adjusting circuitry configured to adjust said analog input signal using said stored error signal.

24. An electronic circuit according to claim 15, wherein the analog to digital converter comprises the digital to analog converter used in a successive approximation analog to digital converter arrangement.

25. An electronic circuit according to claim 15, wherein the digital storage device comprises a digital filter.

26. An electronic circuit according to claim 15, wherein analog components in the electronic circuit are implemented using a switched capacitor arrangement.

27. A portable device comprising:
an electronic circuit according to claim 15; and
a capacitive acceleration sensor for providing the analog input signal.

28. An electronic circuit comprising:
means for storing an analog input signal;
means for converting an analog input signal stored by the analog storage means into a digital signal;
means for storing a digital signal provided by the analog to digital converter; and
means for converting a digital signal stored at the digital storage means into an analog feedback signal.
